(19) United States
(12) Patent Application Publication
(10) Pub. No.: US 2025/0183188 A1
(43) Pub. Date: Jun. 5, 2025

(54) Electric Device and Manufacturing Method thereof

(71) Applicant: InnoLux Corporation, Miao-Li County (TW)

(72) Inventors: Kuang-Ming FAN, Miao-Li County (TW); Chen-Feng LIN, Miao-Li County (TW)

(73) Assignee: InnoLux Corporation, Miao-Li County (TW)

(21) Appl. No.: 18/963,426

(22) Filed: Nov. 27, 2024

Related U.S. Application Data
(60) Provisional application No. 63/606,104, filed on Dec. 5, 2023.
(60) Provisional application No. 63/651,396, filed on May 24, 2024.

(30) Foreign Application Priority Data
Oct. 28, 2024 (CN) 202411508640.3

(51) Int. Cl. H01L 23/538; G06T 7/00; H01L 21/66; H01L 23/13; H01L 25/065

(52) U.S. Cl. CPC H01L 23/5386; G06T 7/0004; H01L 22/24; H01L 23/13; H01L 23/5385; H01L 25/0655; G06T 2207/10061; G06T 2207/30141; G06T 2207/30148

(57) ABSTRACT

A manufacturing method includes providing a substrate including a circuit region and a peripheral region, wherein the peripheral region includes a plurality of test areas; performing a via-forming process on the first substrate, wherein the via-forming process includes forming a test cell in each test area; performing a test cell inspection step to the test cells and comparing the inspection result with inspection standard to obtain a comparison result; based on the comparison result, determining whether the parameters of the via-forming process need to be modified, or whether at least a through via or cavity of the substrate is qualified or needs to be reworked, or whether the substrate needs to be scrapped; and when the through via or cavity is determined to be qualified, forming a conductive layer in the through via or disposing an electronic unit in the cavity.

### CROSS REFERENCE TO RELATED APPLICATION

This application claims the benefit of U.S. Provisional Application No. 63/606,104, filed on Dec. 5, 2023. Further, this application claims the benefit of U.S. Provisional Application No. 63/651,396, filed on May 24, 2024. The contents of these applications are incorporated herein by reference.

### BACKGROUND OF THE DISCLOSURE

### 1. Field of the Disclosure

The present disclosure provides an electronic device and a method of manufacturing an electronic device, with particular reference to a method of manufacturing an electronic device employing a non-destructive inspection step and the manufactured electronic device.

### 2. Description of the Prior Art

Using through via substrates as circuit boards is very favorable for electrical signal transmission because through via substrates have dimensional stability, adjustable thermal expansion coefficient, low power loss at high frequency, high thermal stability, and the ability to be formed in a certain thickness and large panel size. In addition, as the size of electronic units continues to shrink and become lighter and thinner, the three-dimensional chip packaging method of forming cavities in the through via substrate and placing electronic units in the cavities has become popular. Therefore, as the critical dimensions (e.g., through via opening, through via angle) of the TV process of the through via substrate continue to shrink, it directly affects the difficulty of subsequent through via defect inspection and through via metallization processes. In addition, the quality inspection of through via substrates is also an issue that needs to be discussed urgently.

### SUMMARY OF THE DISCLOSURE

Therefore, the purpose of the present disclosure is to provide an electronic device and an electric device manufacturing method.

The present disclosure provides an electronic device, comprising a first substrate having a first surface and a second surface opposite to each other, wherein the first substrate comprises a first cavity disposed in the first surface, and the first cavity having a first bottom surface; a first electronic unit disposed in the first cavity; a circuit structure disposed on the first surface and the first electronic unit; and a printed circuit board electrically connected to the first electronic unit through the circuit structure, wherein a roughness of the first bottom surface of the first cavity is greater than a roughness of the first surface.

The present disclosure provides an electronic device manufacturing method, comprising providing a substrate, wherein the substrate comprises a circuit region and a peripheral region adjacent to the circuit region, and the peripheral region comprises a plurality of test areas; performing a via-forming process on the substrate, wherein the via-forming process comprises forming a test cell in each of the plurality of test areas; performing a test cell inspection step to the plurality of test cells and comparing an inspection result with an inspection standard to obtain a comparison result; based on the comparison result, determining whether parameters of the via-forming process need to be modified, or determining whether at least one through via or cavity of the substrate is qualified or needs to be reworked or whether the substrate needs to be scrapped; and forming a conductive layer in the at least one through via or providing an electronic unit in the at least one cavity when the at least one through via or cavity is determined to be qualified.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a cross-sectional schematic diagram of an electronic device according to a first embodiment of the present disclosure.

FIG. 2 is a cross-sectional schematic diagram of a first cavity of an electronic device according to another embodiment of the present disclosure.

FIG. 3 is a cross-sectional schematic diagram of an electronic device according to a second embodiment of the present disclosure.

FIG. 4 is a cross-sectional schematic diagram of an electronic device according to a third embodiment of the present disclosure.

FIG. 5 is a schematic diagram of a manufacturing system of the electronic device according to the present disclosure.

FIG. 6 is a schematic diagram of an electronic device manufacturing method according to the present disclosure.

FIG. 7 is a top view schematic diagram of the substrate according to the present disclosure.

FIG. 8 is a schematic diagram of the inspection device according to a first embodiment of the present disclosure.

FIG. 9 is a schematic diagram of the inspection device according to a second embodiment of the present disclosure.

FIG. 10 is a schematic diagram illustrating 2D image and 2.5D image of the through via in the substrate according to the present disclosure.

FIG. 11 is a projection schematic diagram of the 2.5D image according to the present disclosure.

FIG. 12 is a schematic diagram of an electronic device having a cavity according to a first embodiment of the present disclosure.

FIG. 13 is a schematic diagram of an electronic device having a cavity according to a second embodiment of the present disclosure.

### DETAILED DESCRIPTION

The present disclosure may be understood by reference to the following detailed description of embodiments, taken in conjunction with the drawings as described below. It is noted that, for purposes of illustrative clarity and being easily understood by the readers, various drawings of this disclosure show a portion of the device or structure, and certain elements in various drawings may not be drawn to scale. In addition, the number and dimension of each element shown in drawings are only illustrative and are not intended to limit the scope of the present disclosure.

Certain terms are used throughout the description and following claims of the present disclosure for Please refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to”. When the terms “comprising”, “including” and/or “having” are used in this specification, they designate the presence of the stated feature, region, step, operation and/or element, but do not exclude the presence or addition of one or more other features, regions, steps, operations, elements and/or combinations thereof.

When an element or layer is referred to as being on or connected to another element or layer, it should be understood that the element or layer is directly on or connected to another element or on another layer, or there may be other elements or layers between the two (indirectly circumstance). However, on the contrary, when the element or layer is referred to being “directly on” or “directly connected to” another element or layer, it should be understood that no intervening elements or layers are existed therebetween.

The directional terms mentioned in the embodiments, such as “up”, “down”, “left”, “right”, “front”, “back”, etc., are only directions referring to the drawings. Therefore, the directional terms used are for illustration, not for limitation of the present disclosure.

In the specification, the terms “about”, “substantially”, “around”, and “approximately” generally mean within 10% of a given value or range, or mean within 5%, 3%, 2%, 1%, or 0.5% of a given value or range. A given quantity herein is an approximate quantity, that is, even in the situation of an absence of a specific description of “about”, “substantially”, “around”, or “approximately”, it may still imply the meaning of “about”, “substantially”, “around”, or “approximately”.

The term “between value A and value B” is interpreted to include the condition of value A and value B or at least one of value A and value B, as well as other values between value A and value B.

In the present disclosure, the thickness, the length, and the width may be measured by an optical microscopy (OM), and the thickness and the length may be measured through a cross-sectional image of a scanning electron microscope (SEM), but not limited thereto. In addition, some errors or inaccuracy may exist between any two values or directions used for comparison.

In the present disclosure, the definition of roughness determination may be observed by SEM, and the peaks and valleys of the surface undulations may be seen on the concave and convex surfaces with a distance difference of 0.15 micrometers (μm) to 1 μm. Measurement of roughness judgment may include the use of SEM, transmission electron microscope (TEM), etc., to observe the surface undulation condition under the appropriate and same magnification, and by taking a single length (e.g., 10 μm) of the sample to compare the undulation condition that is the range of its roughness. Here, “appropriate magnification” means the roughness (Rz) or average roughness (Ra) of at least one surface with at least 10 undulating spikes that may be seen under the field of view of this magnification.

The ordinal terms used in the specification and claims, such as “first”, “second”, etc., are used for indicating elements in the claims. They do not imply and represent any sequential order in the claims, nor does it represent the order of a certain claimed element with respect to another claimed element, or the order of The electronic devices described herein may be used in, but are not limited to, semiconductor packaging devices, display devices, light emitting devices, backlighting devices, antenna devices, sensing devices, or splicing devices. The electronic device may be a bendable or flexible electronic device. A display device may be a non-self-luminous display device or a self-luminous display device. Antenna devices may be liquid crystal type antenna devices or non-liquid crystal type antenna devices, and sensing devices may be sensing devices for capacitance, light, heat, or ultrasonic waves, but not limited thereto. The electronic device may include an electronic component, and the electronic component may include a semiconductor component, and the semiconductor component may include, for example, a passive component and an active component, such as a capacitor, a resistor, an inductor, a diode, a transistor, an integrated circuit, and the like. The diode may include a light emitting diode, an optoelectronic diode, or a capacitive diode. The light emitting diode may, for example, include an organic light emitting diode (organic light emitting diode, OLED), a sub-millimeter light emitting diode (mini LED), a micro light emitting diode (micro LED), or a quantum dot light emitting diode (quantum dot LED), but is not limited to this. A splicing device may be, for example, a display splicing device or an antenna splicing device, but is not limited thereto. Semiconductor components may include, but are not limited to, semiconductor layers or electronic components made through a semiconductor process. It should be noted that the electronic device may be in any combination of the foregoing arrangements, but is not limited thereto. The electronic device may have a peripheral system such as a drive system, a control system, a light source system, a shelf system, etc. The electronic device may include an electronic unit. The electronic device may include an electronic unit, wherein the electronic unit may include a passive element and an active element, such as a capacitor, resistor, inductor, diode, transistor, sensor, and the like. It should be noted that the electronic devices of the present disclosure may be various combinations of the above devices, but are not limited thereto. The manufacturing method of the electronic devices disclosed herein may be applied, for example, to wafer-level package (WLP) processes or panel-level package (PLP) processes, wherein the wafer-level package or panel-level package processes may include chip-first processes or chip-last processes, but the wafer-level package or panel-level package processes may include chip-first processes or chip-last processes, but the wafer-level package or panel-level package processes may include chip-last processes. The electronic devices disclosed herein may include, for example, a chip-first process or a chip-last process, but are not limited thereto. The electronic devices of the present disclosure may be used, for example, in power modules, semiconductor packaging devices, display devices, light emitting devices, backlighting devices, antenna devices, sensing devices, or splicing devices, but are not limited thereto. Electronic devices may include, but are not limited to, System on a Chip (SoC), System in a Package (SiP), antenna in package (AiP), or various combinations of the foregoing.

It should be noted that, without departing from the spirit of the present disclosure, features in several different embodiments may be substituted, recombined, or mixed to accomplish other embodiments.

It is to be noted that the technical solutions provided in the different embodiments hereinafter may be substituted, combined or mixed with each other to constitute another embodiment without violating the spirit of the present disclosure.

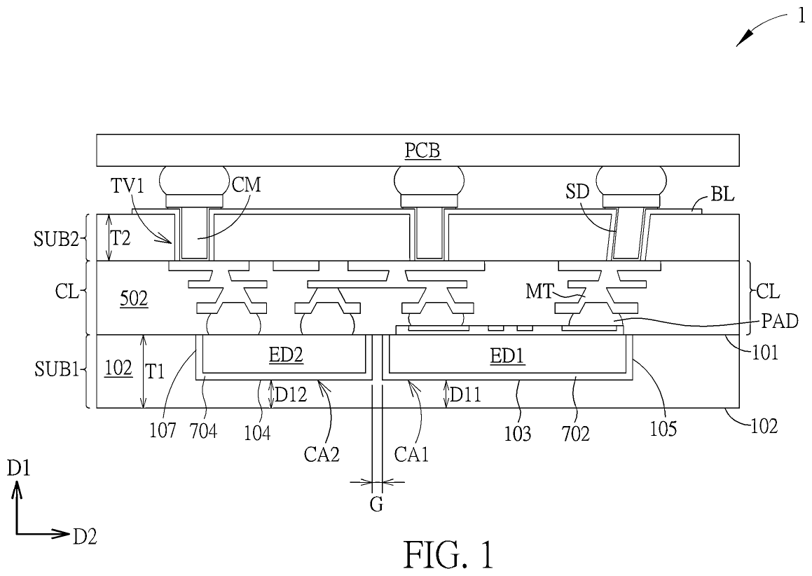

Please refer to FIG. 1. FIG. 1 is a cross-sectional schematic diagram of an electronic device 1 according to a first embodiment of the present disclosure. As shown in FIG. 1, the present disclosure provides an electronic device 1, which includes a first substrate SUB1, a first electronic unit ED1, a circuit structure CL, and a printed circuit board PCB. The first substrate SUB1 may include a transparent substrate or an opaque substrate. The material of the first substrate SUB1 may be a glass, a ceramic, a wafer, an organic material, a combination of the foregoing, or other suitable materials, and the glass may include, but not limited to, fused silica, an alkali glass, or an alkali-free glass. In the embodiment shown in FIG. 1, the first substrate SUB1 may, for example, be a glass substrate. The first substrate SUB1 has a first surface 101 and a second surface 102 opposite to each other, and includes a first cavity CA1 disposed on the first surface 101, i.e., the first cavity CA1 is a cavity recessed inwardly from the first surface 101 of the first substrate SUB1. In this embodiment, the first electronic unit ED1 is disposed in the first cavity CA1 and electrically connected to the printed circuit board PCB through the circuit structure CL. It should be noted that the manufacturing process of the first cavity CA1 may include performing a modification process to the first substrate SUB1, and then performing an etching process or a laser process to the first substrate SUB1 to form the first cavity CA1. Along a first direction D1 (e.g., a normal direction of the first substrate SUB1), the first substrate SUB1 may have a first thickness T1, and the first thickness T1 may ranges from 0.05 millimeters (mm) to 1 mm. The first substrate SUB1 may have a coefficient of thermal expansion (CTE) ranges from 2 (ppm/° C.) to 10 (ppm/° C.).

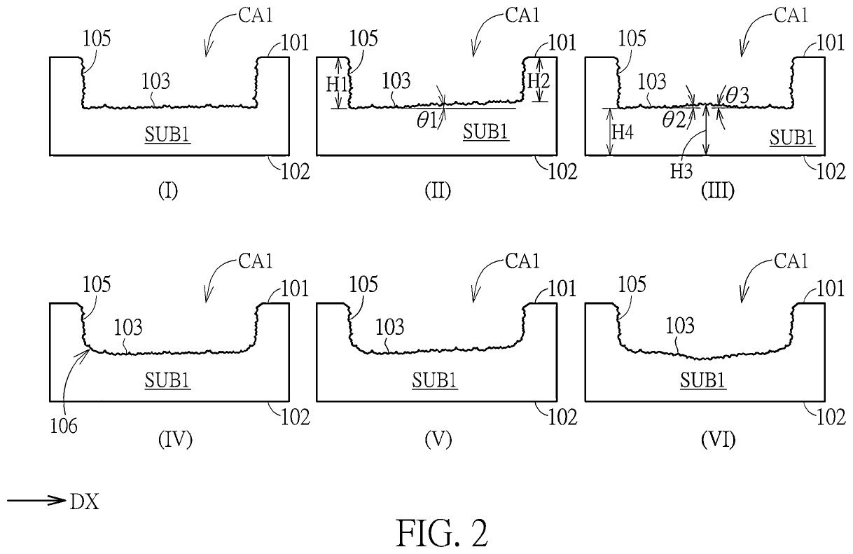

Please refer to FIG. 2. FIG. 2 is a cross-sectional schematic diagram of a first cavity CA1 of an electronic device 1 according to other embodiments of the present disclosure. In detail, the sectional shape of the first cavity CA1 may not have a rectangular profile of a flat bottom surface and sidewalls. In an embodiment, as shown in FIG. 2, a roughness of a first bottom surface 103 of the first cavity CA1 may be larger than a roughness of a first surface 101 of the first substrate SUB1. In the cross-sectional schematic diagram, the first cavity CA1 may include two sidewalls 105 each connecting the first bottom surface 103. As shown in Example (I), the first cavity CA1 has a first bottom surface 103, which may be an uneven surface and have a certain roughness. Furthermore, the sidewalls 105 of the first cavity CA1 may have an extension line substantially perpendicular to the first bottom surface 103 in Example (I). The sidewalls 105 may also be uneven surfaces and have a certain roughness, and the sidewalls 105 have radius angles in close proximity to the first surface 101. In Example (II), the two sidewalls 105 of the first cavity CA1 connected to the first bottom surface 103 may have the same or different heights, for example, the height difference between the height H1 and the height H2 of the two sidewalls 105 ranges from 0 micrometers to 20 micrometers. When the two sidewalls 105 have different heights, it may also indicate that the first bottom surface 103 is a tilted surface, which extends in a direction that is not parallel to the first surface 101 of the first substrate SUB1. For example, the first surface 101 is parallel to a horizontal plane or a horizontal direction DX, while the first bottom surface 103 is not parallel to the horizontal plane or the horizontal direction DX. As shown in Example (II), the first bottom surface 103 may have an included angle θ1 with the horizontal direction DX (e.g., the direction of extension of the substrate SUB1), wherein the included angle θ1 is in a range within 10 degrees. In other words, the tilt angle of the first bottom surface 103 is greater than 0 degrees and less than or equal to 10 degrees (0°<θ1≤10°). In other embodiments, the included angle θ1 is in a range less than or equal to 2 degrees but not 0 degrees (0°<θ1≤2°). In Example (III), the first bottom surface 103 is not parallel to the horizontal plane or the horizontal direction DX either, wherein there is a distance H3 between the center portion of the first bottom surface 103 and the second surface 102, and there is a distance H4 between the intersection (i.e. connection) of the first bottom surface 103 and the sidewall 105 of the first cavity CA1 and the second surface 102, and wherein the distance H3 is greater than the distance H4. In other words, the first bottom surface 103 has a raised center portion while other portions of the first bottom surface 103 are lower. The center portion of the first bottom surface 103 referred to in the present disclosure is half of the maximum width of the first bottom surface 103 and +/−5 micrometers along the horizontal direction. It may also be indicated that the first bottom surface 103 of the first cavity CA1 is inclined in different directions in the portions close to the two sidewalls 105, for example, there may be an included angle θ2 and an included angle θ3 of approximately equal size between the horizontal direction DX and the outer edge portions at two sides of the center portion of the first bottom surface 103 respectively, but not limited thereto. In Example (IV), an included angle between the sidewall 105 and the first bottom surface 103 of the first cavity CA1 is in the shape of a radius angle or a chamfering angle 106. In Example (V), the first bottom surface 103 of the first cavity CA1 is inclined and has an included angle with the horizontal direction DX, the first bottom surface 103 has a radius angle at the connection to the sidewall 105, and the first bottom surface 103 is coupled to the sidewall 105 with a radius angle. In addition, the sidewall 105 has a chamfering angle at the connection to the first surface 101. In Example (VI), the center portion of the first bottom surface 103 is higher than the outer edge portion, and the outer edge portion has a chamfering angle. The present disclosure may produce the first cavity CA1 by laser drill process or by laser modification and chemical etching. Therefore, the cavity may be affected by the inclination angle of the laser Galvo scanner oscilloscope or the uniformity of the etching for example, so that the first bottom surface 103 of the first cavity CA1 will have a certain roughness. According to the present disclosure, the roughness of the first bottom surface 103 as inspected or designed is greater than 0 micrometers and less than or equal to 2 micrometers, the inclination angle of the first bottom surface 103 is ≤10°, the connection between the first bottom surface 103 and one of the two sidewalls 105 may form a right-angle profile, a radius-angle (R-angle) profile, or a conduction-angle (C-angle) profile, or the height difference between the two sidewalls 105 connecting the first bottom surface 103 is between 0.5 mm and 2 mm, or a height difference between the two sidewalls 105 connecting the first bottom surface 103 is between 0 micrometers and 20 micrometers. As shown in Example (I) to Example (VI), this may enhance the reliability of the electronic device, but not limited to.

Please refer to FIG. 1, the electronic device 1 optionally includes an adhesive layer 702 that secures the first electronic unit ED1 in the first cavity CA1, and the adhesive layer 702 may be, for example, a die attach film (DAF) or other suitable adhesive layer, but is not limited thereto. According to some embodiments, the adhesive layer 702 may include filler particles dispersed in an organic material, wherein the filler particles may include metals, silicon carbide, graphene, carbides, oxides, combinations of the foregoing, or other suitable materials. Filler particles for enhancing heat dissipation and filler particles for adjusting the coefficient of thermal expansion of the adhesive layer 702 may be added at the same time to enhance the reliability or heat dissipation of the electronic device, but not limited to. Furthermore, a contact pad PAD may be disposed on the surface of the circuit structure CL to electrically connect to the first electronic unit ED1 through the conductive layer MT. The contact pad PAD may include tin, copper, nickel, gold, gallium, platinum, combinations of the above or other suitable materials. The circuit structure CL may be a redistribution layer (RDL) structure including one or a plurality of insulating layers 502, and the conductive layer MT may be disposed on the surface of the insulating layer 502 and in the through vias of the insulating layer 502. It should be noted that the electronic device 1 illustrated in FIG. 1 also includes a second substrate SUB2 including a plurality of through vias TV1, a buffer layer PL covering at least a portion of the surface of the second substrate SUB2 and extending into the through vias, a seed layer SD disposed on the buffer layer PL and extending into the through vias, and a conductive material CM disposed on the seed layer SD and filling the plurality of through vias. Other electronic units or wires may contact the conductive material CM of the electronic device 1 either directly or indirectly through intermediate conductive material for electrical signal transmission. It should be noted that the other electronic units or wires and the intermediate conductive material are well known in the art for those skilled in the field, and will not be repeated herein. The circuit structure CL described in the present disclosure allows for the rewiring of wires and/or increasing the fan-out area of wires, or different electronic units may be electrically connected to each other through the redistribution layer structure. The method of forming the redistribution layer structure may include providing a stack including at least one insulating layer and at least one conductive layer, which may include processes such as lithography, etching, surface treatment, laser, plating, and the like. Surface treatment includes roughening the surface of the insulating layer or the surface of the conductive layer to improve its connection ability, or may be applied to a substrate for wiring the electrical interface between one connection and another. The purpose of the circuit structure CL or the redistribution layer structure is to extend the connection to a wider spacing or to redistribute the connection to another connection with a different spacing. The insulating layer 502 may include polyimide (PI), photosensitive polyimide (PSPI), polybenzoxazole (PBO), epoxy resin, Ajinomoto Build-up Film (ABF), silicon oxide (SiO), silicon oxide (SiOx), silicon nitride (SiNx), any other suitable insulating material or a combination of the above materials, but not limited to. The conductive layer MT may include any suitable conductive material, such as copper, titanium, nickel, gallium, tungsten or combinations or alloys of the above materials, but not limited to. In some embodiments, the thickness of the insulating layer 502 may range from about 2 μm to about 15 μm. In some embodiments, the thickness of the insulating layer 502 may be greater than the thickness of the buffer layer PL. The buffer layer PL may help to ameliorate the negative effects of the process of forming the through via TV1 described above on the carrier substrate SUB2. For example, the buffer layer PL may repair the defects (e.g., micro cracks) caused by the above-described processes of forming the through-via TV1 in the second substrate SUB2 through a modification process (e.g., a laser modification process) and an etching process. In other embodiments, for example where the second substrate SUB2 is a glass substrate, the buffer layer PL may mitigate differences in the coefficient of thermal expansion (CTE) between the second substrate SUB2 and the conductive material CM subsequently formed in the through via TV1 to improve the adhesion of the conductive layer formed in the through via TV1. In some embodiments, the buffer layer PL is disposed at least on the sidewalls of the through via TV1 and extends over the upper and lower surfaces of the second substrate SUB2 opposite to each other in the first direction D1.

The buffer layer PL may include a single layer or a multi-layer stack. The buffer layer PL may include organic or inorganic materials. Organic materials may include, for example, polyimide (PI), parylene, benzocyclobutene (BCB), epoxy resin, polycarbonate (PC), polyethylene terephthalate (PET), polyethylene naphthalate (PEN) or a combination of the above, but not limited to. The toughness of the buffer layer PL may be from 0.1 kJ/m² to 100 KJ/m². Inorganic materials may include silicon oxide, silicon nitride, nitride, oxide, carbide, or combinations of the foregoing, but are not limited to. Furthermore, the buffer layer PL may include at least one organic material layer, or the buffer layer PL may include at least one organic material layer and an inorganic material layer formed on the organic material layer, or the buffer layer PL may include at least two organic material layers and an inorganic material layer formed between the two organic material layers, that is, the organic material layer and the inorganic material layer may be stacked alternately. The thickness of the buffer layer PL may be from about 0.01 μm to about 10 μm. In this embodiment, the maximum thickness of the buffer layer PL may be less than about 1 μm. The dissipation factor (Df) of the buffer layer PL may be less than 0.01 at 10 GHz. The ratio of the thickness of the buffer layer PL to the width W of the through via TV1 may be from about 0.02 to about 0.2.

Furthermore, with continued reference to FIG. 1, the electronic device 1 of the present disclosure may include a plurality of cavities, wherein at least two of the cavities have different profile shapes, while some of the cavities of the plurality of cavities of the electronic device 1 may have the same profile shape. In an embodiment, as shown in FIG. 1, the first substrate SUB1 of the electronic device 1 further includes a second cavity CA2 adjacent to the first cavity CA1, or the second cavity CA2 and the first cavity CA1 are arranged in a second direction D2, which may be perpendicular to the first direction D1. In other words, the second cavity CA2 is disposed on the first surface 101 and disposed at one side of the first cavity CA1. The electronic device 1 further includes a second electronic unit ED2 disposed in the second CA2 and electrically connected to the printed circuit board PCB through the circuit structure CL. It should be noted that a roughness of a second bottom surface 104 of the second cavity CA2 is larger than that of the first surface 101, and the roughness of the second bottom surface 104 of the second cavity CA2 may be the same or different from the roughness of the first bottom surface 103. The difference between the roughness of the first bottom surface 103 and the roughness of the second bottom surface 104 is in a range greater than or equal to 0 micrometers and less than or equal to 5 micrometers. In an embodiment, the included angle between the extension direction of the second bottom surface 104 of the second cavity CA2 and the extension direction of the first bottom surface 103 of the first cavity CA1 ranges from 0 degrees to 10 degrees. In another embodiment, the first cavity CA1 has a sidewall 105, the second cavity CA2 has a sidewall 107, and the height difference between the sidewall 107 and the sidewall 105 is in a range greater than or equal to 0 micrometers and less than or equal to 20 micrometers. The sectional profile of the second cavity CA2 may be one of the example (I) to example (VI) shown in FIG. 2. The sectional profile of the second cavity CA2 may be the same as or similar to that of the first cavity CA1, or the sectional profile of the second cavity CA2 may be different from that of the first cavity CA1. For example, the sectional profile of the second cavity CA2 and the sectional profile of the first cavity CA1 may be two different profiles among the examples (I) to (VI) respectively, but not limited to. Furthermore, an adhesive layer 704 may be disposed in the second cavity CA2 for securing the second electronic unit ED2. In an embodiment, the first electronic unit ED1 and the second electronic unit ED2 may be the same or different chips, such as chips of different sizes and/or with different functions. Under the circumstance, the size of the first cavity CA1 may be different from the size of the second cavity CA2.

Referring back to FIG. 1, along the first direction D1, a thickness D11 is defined between the first bottom surface 103 of the first cavity CA1 and the second surface 102 of the first substrate SUB1, a thickness D12 is defined between the second bottom surface 104 of the second cavity CA2 and the second surface 102 of the first substrate SUB1, wherein the thickness D11 and the thickness D12 may be the same or different. For example, when the size of the first electronic unit ED1 is smaller than that of the second electronic unit ED2, the thickness D11 may be larger than the thickness D12, where a ratio of the thickness D12 to the first thickness T1 may be between 0.2 and 0.7 for providing good support ability, but is not limited thereto. Furthermore, in a second direction D2 perpendicular to the first direction D1, there is a spacing G between neighboring cavities, the spacing G may be greater than or equal to 5 micrometers. By the above design, the probability of cracking of the substrate may be reduced, but not limited thereto.

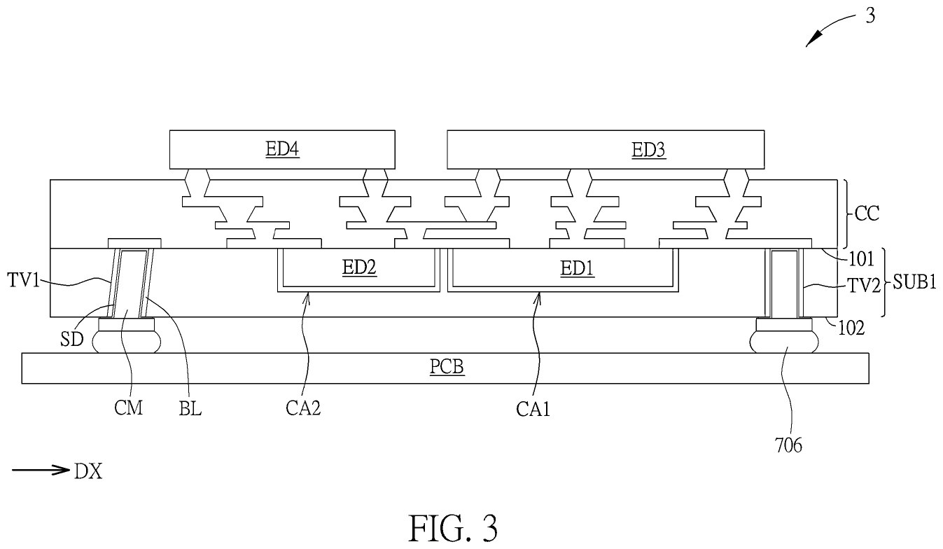

It should be noted that the structure and method of making the layers of the electronic device 1 are well known in the art, and those skilled in the art may combine, modify, or change the above-described embodiments in accordance with the spirit of the present disclosure, without being limited thereto. For example, please refer to FIG. 3, which is a cross-sectional schematic diagram of an electronic device 3 according to a second embodiment of the present disclosure. As shown in FIG. 3, the present disclosure provides an electronic device 3. The electronic device 3 further includes a third electronic unit ED3 and a fourth electronic unit ED4 electrically connected to the first electronic unit ED1 disposed in the first cavity CA1 and to the second electronic unit ED2 disposed in the second cavity CA2 through the circuit structure CL. In the embodiment illustrated in FIG. 3, the first substrate SUB1 may further include one or more through vias, such as through via TV1 and through via TV2, in which a conductive material CM may be disposed, and the conductive material CM may be electrically connected to the printed circuit board PCB through a bonding material 706, such as, but not limited to, a bump or a solder. The printed circuit board PCB may be electrically connected to the circuit structure CL through the conductive material CM in the through via TV1 and through via TV2. In an embodiment, the sidewalls of the through via TV1 and the through via TV2 may extend in directions that are not parallel to each other. For example, the sidewall of the through via TV1 may extend in a direction that is not parallel to the normal direction of the first surface 101, but not limited thereto. It should be noted that other electronic units or wires and intermediate conductive materials are well known to those skilled in the art and will not be repeated herein.

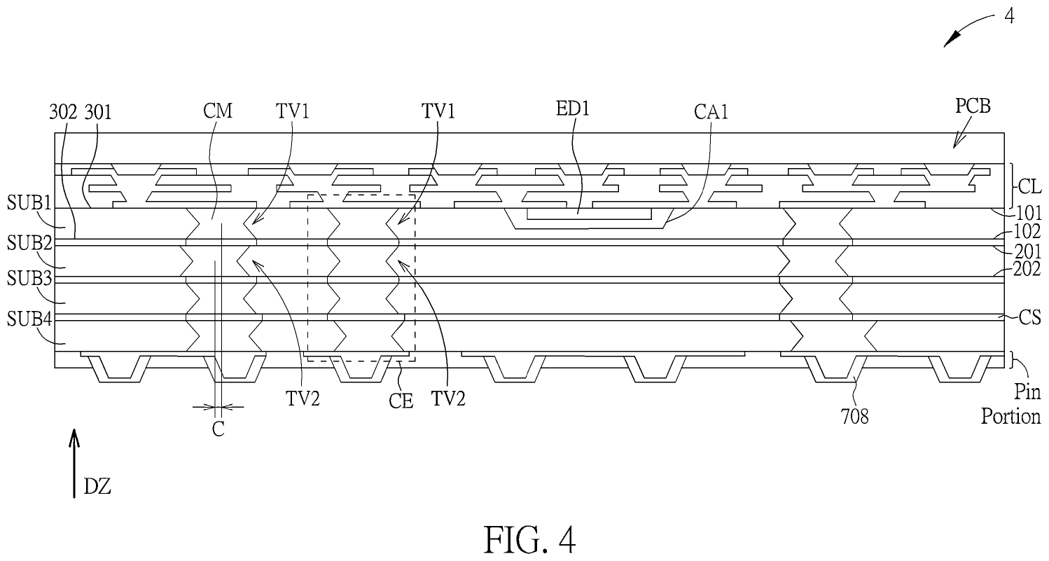

Please refer to FIG. 4. FIG. 4 is a cross-sectional schematic diagram of an electronic device 4 according to a third embodiment of the present disclosure. As shown in FIG. 4, the present disclosure provides an electronic device 4, which may be applied as a probe card interposer, but is not limited thereto. The electronic device 4 includes a plurality of substrates (SUB1, SUB2, SUB3, SUB4) stacked in a first direction, a plurality of through vias, and a conductive material CM. The substrate SUB may be glass, ceramics, wafers, organic materials, combinations of the foregoing, or other suitable materials, and the glass may include, but is not limited to, fused silica, alkali glass, or alkali-free glass. The conductive material CM may be filled in the plurality of through vias, and other electronic units or wires may contact the conductive material CM of the electronic device 4 either directly or indirectly through intermediate conductive materials for electrical signal transmission. Between neighboring substrates SUB, the upper and lower substrates SUB may be coupled and fixed by using an intermediary layer, the intermediary layer including a conductive polymer, resin, glue, glass-based material, or other suitable material to adhere and fix the upper and lower substrates SUB, wherein the intermediary layer includes a conductive material or an insulating material, but not limited thereto. As shown in FIG. 4, the first substrate SUB1 may include at least one cavity and at least one through via TV1. The plurality of substrates are stacked along the normal direction DZ of the first substrate SUB1, and the plurality of substrates each include at least one through via TVN (N≥2, N being an integer) such that the through via of each substrate are substantially overlapped; in other words, the projection areas of the through via located on each substrate are substantially overlapped. For the sake of easy understanding and simplicity of the drawings, the description herein focuses only on the first substrate SUB1 and the second substrate SUB2 of the electronic device 4. The first substrate SUB1 has a first surface 101 and a second surface 102, and includes at least one first through via TV1 connecting the first surface 101 and the second surface 102. In an embodiment, the first substrate SUB1 includes a plurality of first through vias TV1 disposed side by side with each other. The second substrate SUB2 is disposed on one side of the second surface 102 of the first substrate SUB1, the second substrate SUB2 has a third surface 201 and a fourth surface 202 opposite to each other, and the second substrate SUB2 includes at least one second through via TV2 connecting the third surface 201 and the fourth surface 202. In an embodiment, the second substrate SUB2 includes a plurality of second through vias TV2 disposed side by side with each other. In the normal direction DZ of the first substrate SUB1, each of the second through vias TV2 overlaps and corresponds to a first through via TV1. It should be noted that in the normal direction DZ of the first substrate SUB1, one first through via TV1 has a first projection area on the first surface 101, the corresponding second through via TV2 has a second projection area on the first surface 101, and the first projection area overlaps with at least a portion of the second projection area. That is, the first through via TV1 partially overlaps at least with the second through via TV2 in the normal direction DZ of the first substrate SUB1. In addition, in the normal direction DZ of the first substrate SUB1, the degree to which the first projection region and the second projection region are similar to a circular shape varies, but is not limited thereto. For example, the concentricity angle of the first projection region and the concentricity angle of the second projection region are greater than or equal to 90%, respectively. For example, the extension direction of the sidewall of the first through via TV1 may not be exactly parallel to the stacking direction, such as but not limited to presenting an hourglass profile. The concentricity angle may be measured by taking at least three cross-sections of any portion of the first through via TV1, obtaining at least three diameters, and obtaining ideal circular shapes of each of those diameters, and the overlapping area of those circular shapes is regarded as the concentricity angle, wherein the above mentioned concentricity angle of greater than or equal to 90% refers to the overlap rate of the at least three ideal circular shapes obtained by the above mentioned measurement method being greater than or equal to 90%. Alternatively, the concentricity angle may be measured by obtaining at least two diameters (e.g., a long axis diameter “a” and a short axis diameter “b”) after projection of the first through via TV1, and the ratio R of the short axis diameter “b” to the long axis diameter “a” is the concentricity angle (i.e., R=b/a). In addition, in an embodiment, a distance C between a first center of a first projection area and a second center of a second projection area is less than or equal to 10 micrometers, which represents a concentricity distance, i.e., a center misalignment anomaly, between the first through via TV1 and the second through via TV2. Alternatively, referring back to FIG. 4, according to some embodiments, the location of the center of the circle is the center of the minimum width of the through via. In another embodiment, the first substrate SUB1 and the second substrate SUB2 have a thickness ranging from 25 micrometers to 500 micrometers, respectively. In another embodiment, the first substrate SUB1 and the second substrate SUB2 have a thickness ranging from 25 micrometers to 200 micrometers, respectively. In addition, as previously described, in the sectional structure of the electronic device 4, the sidewall profile of at least one of the first through via TV1 and the second through via TV2 has an included angle α with the normal direction DZ of the first substrate SUB1, wherein the included angle α may be greater than or equal to 2 degrees and less than or equal to 20 degrees. In addition, the electronic device 4 may also include a first cavity CA1 disposed on the first surface 101, i.e., the first cavity CA1 is a cavity recessed inwardly from the first surface 101 of the first substrate SUB1. The electronic device 4 may also include a circuit layer CL disposed on the first substrate SUB1 and a printed circuit board PCB disposed on the circuit layer CL, and the electronic device 4 may further include another circuit layer CL1 disposed on a side of the stacked plural substrates SUB opposite to the printed circuit board PCB. The circuit layer CL and the circuit layer CL1 may each be a redistribution layer structure, but not limited to. The lower side of the circuit layer CL1 may be provided with a bump 708 or a bonding material. It should be noted that the first electronic unit ED1 is disposed in the first cavity CA1 in this embodiment and is electrically connected to the printed circuit board PCB through the circuit structure CL. According to the present disclosure, the through vias in the respective substrates SUB may be made by laser drilling or by laser modification followed by etching. In the manufacturing method, the through vias in each substrate SUB may be formed separately and filled with conductive material CM, and then the plurality of substrates SUB may be stacked to form a complete probe card interposer with conductive function. This manufacturing method may improve the alignment accuracy of the through vias between different substrates SUB, so that the overlapping through vias and the filled conductive material may form a conductive element CE with good electrical effect, which may penetrate from the topmost substrate SUB to the lowest substrate SUB, and thus may effectively improve the yield of the product. The electronic unit described herein may include a semiconductor chip, an integrated circuit chip, a resistor, a capacitor, an inductor, a combination of the above, or other suitable components, but is not limited thereto.

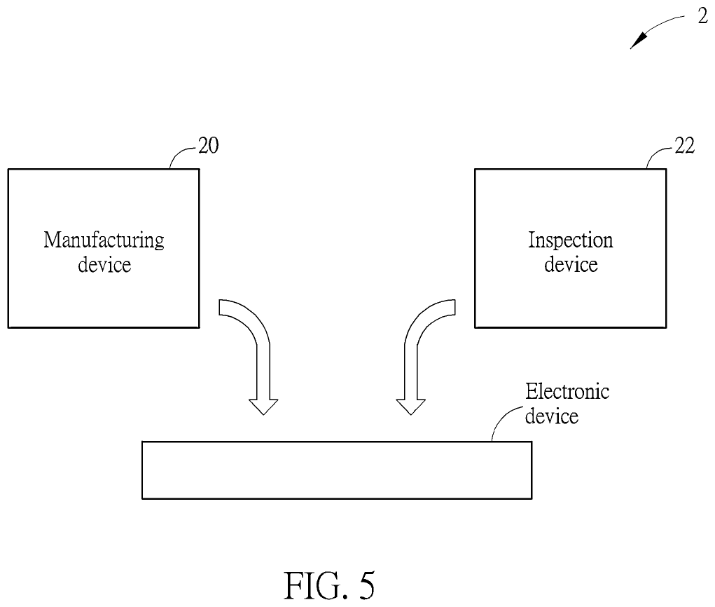

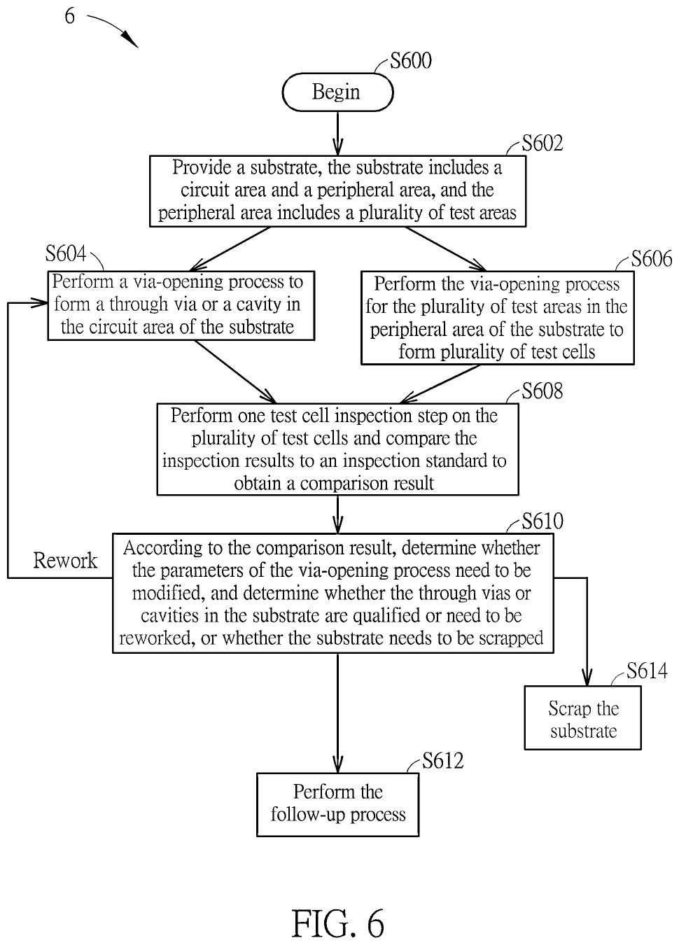

Please refer to FIG. 5. FIG. 5 is a schematic diagram of a manufacturing system 2 of the electronic device according to the present disclosure. As shown in FIG. 5, the manufacturing system 2 includes a manufacturing device 20 and an inspection device 22, which is used to inspect whether the electronic device 1 or the electronic device 4 manufactured by the manufacturing device 20 includes abnormal or defective cavities or through vias, or inspect the performance of the modification process before forming the cavities and through vias. The manufacturing device 20 may rework the electronic device 1 or electronic device 4 according to the inspection results. It should be noted that the manufacturing device 20 and the inspection device 22 may be separate devices or integrated into one device, or the manufacturing device 20 and/or the inspection device 22 may integrate a controller or other computing device (e.g., an edge computing device) to determine inspection results, but no limited to. In detail, the operation of the manufacturing system 2 may be summarized in an electronic device manufacturing method 6, as shown in FIG. 6. The electronic device manufacturing method 6 includes the following steps:
Step S600: Begin.
Step S602: Provide a substrate, the substrate includes a circuit region and a peripheral region, and the peripheral region includes a plurality of test areas.
Step S604: Perform a hole-forming process to the circuit region of the substrate to form a through via or a cavity.
Step S606: Perform a hole-forming process to the plurality of test areas in the peripheral region of the substrate to form a plurality of test cells.
Step S608: Perform a test cell inspection step on the plurality of test cells and compare the inspection result(s) to an inspection standard to obtain a comparison result.
Step S610: Based on the comparison result, determine whether the parameters of the hole-forming process need to be modified, and determine whether the through vias or cavities in the substrate are qualified or need to be reworked, or whether the substrate needs to be scrapped.
Step S612: Perform the follow-up process.
Step S614: Scrap the substrate.

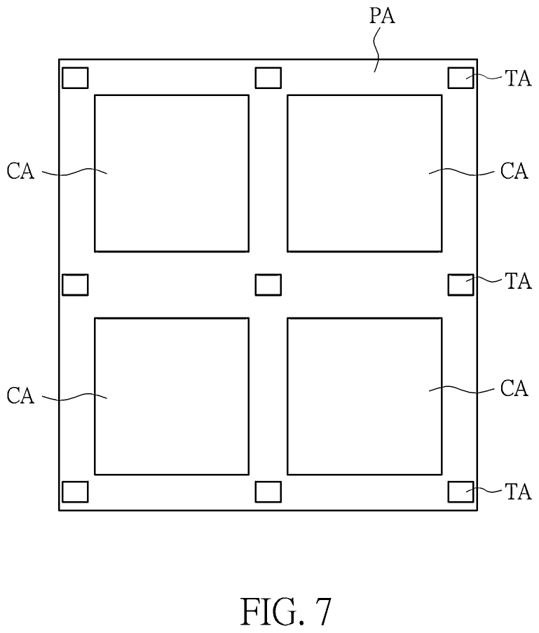

According to step S602, step S604, and step S606 of the electronic device manufacturing method 6, please refer to FIG. 7, which is a top view schematic diagram of the substrate SUB according to the present disclosure. The substrate SUB includes a circuit region CA and a peripheral region PA adjacent to the circuit region CA, and the peripheral region PA includes a plurality of test areas TA. The manufacturing device 20 performs a hole-forming process for the substrate SUB to form at least one through via or cavity (such as the first cavity CA1, the second cavity CA2, the first through via TV1, or the second through via TV2, as shown in FIG. 1 to FIG. 4) in the circuit region CA, and simultaneously forms a test cell in each of the test areas TA. It should be noted that the test cells corresponding to different test areas may have the same or different test parameters respectively. For example, the test cells may have similar structures corresponding to the through vias or cavities formed in the predetermined circuit region CA, but each test cell may have different depths or sizes respectively. In the nine test areas in FIG. 7, nine test cells with different parameters may be formed, but are not limited to this. In addition, steps S604 and S606 may be performed simultaneously, i.e., the through vias or cavities in the peripheral zone PA may be made together with the test cells in the test areas TA. According to some embodiments, the test cells of the test areas TA may be formed first, and the fabrication of the through vias or cavities in the peripheral region PA may be carried out after one or more of the test cells of the test area TA have been inspected for compliance with or meet the specification. The reliability or yield of the electronic device may be enhanced through the above-mentioned processes, but not limited to the above.

In step S608, the inspection device 22 may perform a test cell inspection step on the plurality of test cells and compare the inspection results with an inspection standard to obtain a comparison result, wherein the test cell inspection step includes utilizing a 2.5D image measurement method to obtain the inspection result. The data comparison may be done by importing artificial intelligence (AI) tools or by using a graphics processing unit (GPU) to provide powerful computing capability for data processing and comparison, which may provide the function of real-time monitoring and feedback. In step S610, the inspection device 22 may determine whether the parameters of the hole-forming process need to be modified according to the comparison results, and determine whether the through vias or cavities of the substrate are qualified or need to be reworked, or the substrate needs to be scrapped. If qualified, step S612 is performed; if rework is required, step S604 may be performed; and if scrap is required, step S614 is performed. Alternatively, if the cavity is determined to be qualified, an electronic unit may be disposed in the cavity. It should be noted that the above inspection standard includes: in the inspection standard establishment stage, obtaining 2.5D images of a plurality of through vias or a plurality of cavities through non-destructive 2.5D image measurement; when the 2.5D images show that one of the plurality of through vias or the plurality of cavities has an uneven sidewall, performing a destructive measurement to the one of the through vias or the cavities, to obtain the parameter data of the uneven sidewall, and collecting the parameter data and the 2.5D image corresponding to the parameter data; and repeating the above steps to establish the collected data as the inspection standard.

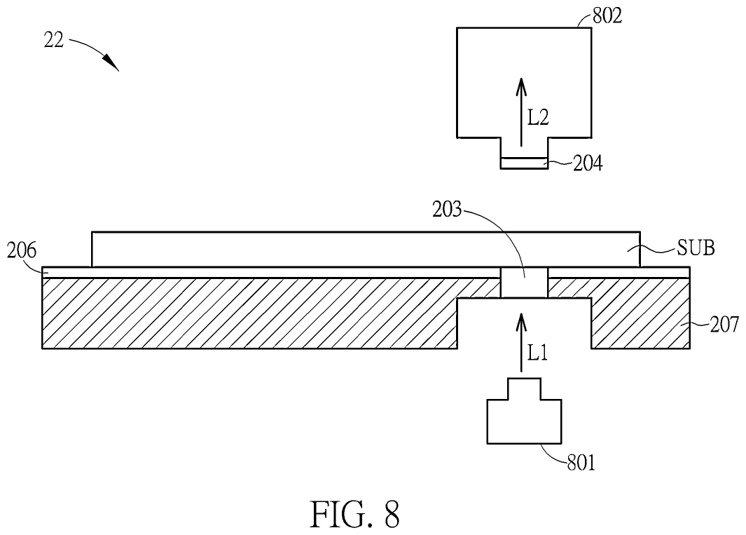

In detail, please refer to FIG. 8, which is a schematic diagram of the inspection device 22 according to a first embodiment of the present disclosure. The inspection device 22 includes a first inspection light generator 801, an inspection light receiver 802, and a first optical film assembly 203, and optionally includes a carrier table 207. The first inspection light generator 801 may provide a first light L1, and enable the first light L1 to pass through the first optical film assembly 203, and then pass through at least one of the plurality of test cells in the substrate SUB. The first optical film assembly 203 may include a polarizer. In other words, the first optical film assembly 203 may be considered as a polarization generator. When the first light L1 passes through the first optical film assembly 203, a collimated light is provided, and after the collimated light passes through at least one of the plurality of test cells, the inspection light receiver 802 receives the collimated light and produces an inspection result. The detected light receiver 202, for example, is a camera unit which may include a second optical film assembly 204, and the second optical film assembly 204 may include another polarizer whose polarization direction is different from, such as orthogonal to, the polarization direction of the polarizer of the first optical film assembly 203. In the above-described design, the second optical film assembly 204 may be regarded as including an analyzer or a polarizer, which may be used to detect the polarization of the received light. During the inspection process, when the first light L1 including collimated light passes through the inspection area, at least one of the plurality of test cells has different refractive properties. For example, some of the test cells will cause the first light L1 to have a larger refractive angle. When the first light L1 enters the inspection light receiver 802, it will first pass through the first optical film assembly 203 to form the second light L2, and then the camera system in the inspection light receiver 802 may obtain a 2.5D image and generate an inspection result accordingly. In this embodiment, the carrier table 207 may be a black anodized platform, but not limited to the above, and the carrier table 207 may also have other colors or be unanodized. Through the above design, the image determination may be more obvious and the defect detectable rate may be improved, but not limited to. According to some embodiments, the inspection device 22 may further include an ultrasonic device, a heatable ultrasonic device, or other suitable inspection device. The ultrasonic device may be coupled to the receiver 202′, and the test cell may be disposed in the ultrasonic device, the heatable ultrasonic device, or other devices, so that through the different transmission speeds of the components to the thermal, acoustic, and oscillatory waves, it may be possible to determine whether or not there are defects, and at the same time, together with the inspection of the optical inspection device, it may be possible to enhance the reliability of the electronic device or determine whether or not it is possible to carry out the rework.

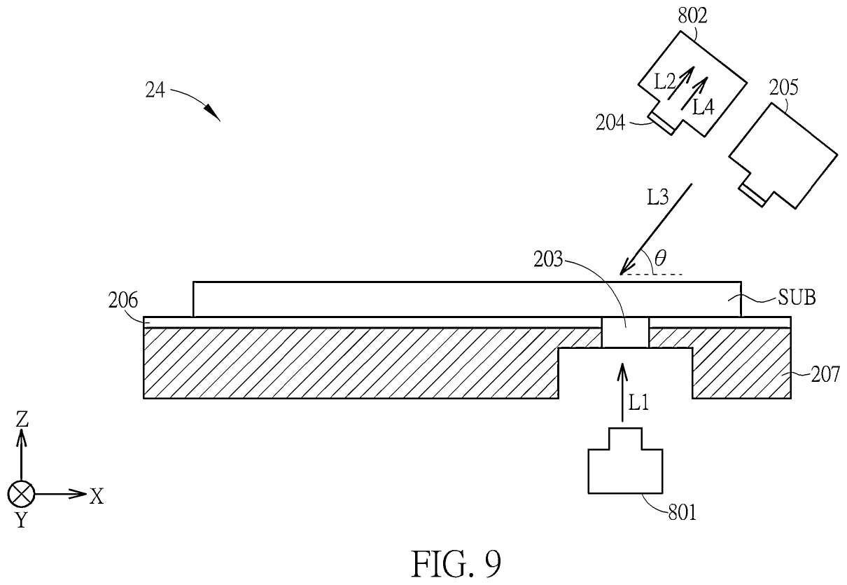

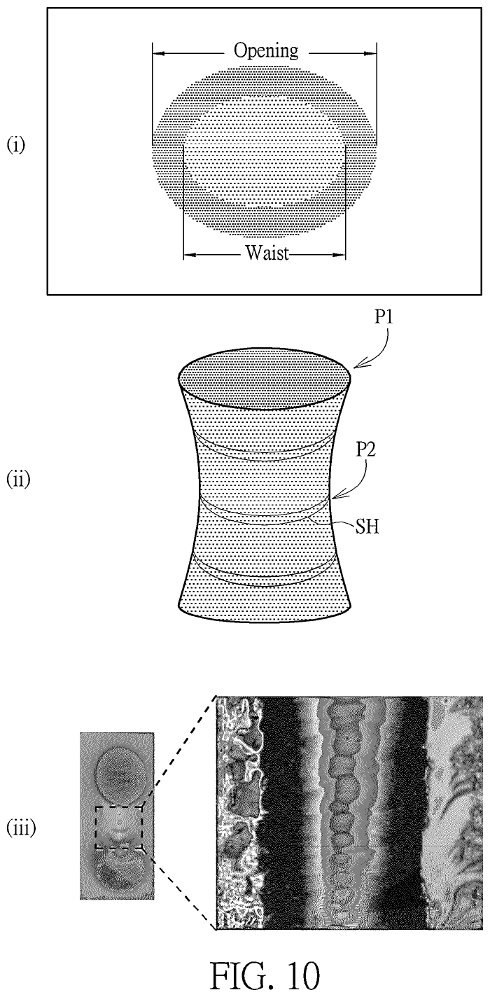

On the other hand, the inspection device of the presently disclosed electronic device may utilize not only a backlight source (corresponding to the lower surface of the substrate SUB) such as the first inspection light generator 801 to detect the electronic device, but also a front light source (corresponding to the upper surface of the substrate SUB) to detect the electronic device. Please refer to FIG. 9, FIG. 9 is a schematic diagram of the inspection device 24 according to a second embodiment of the present disclosure. The inspection device 24 may be derived from the inspection device 22, so the same components are indicated by the same symbols. The difference between the inspection device 24 and the inspection device 22 is that the inspection device 24 also includes a second inspection light generator 205 and a third optical film (layer) assembly 206. The second inspection light generator 205 is disposed on the side of the upper surface of the substrate SUB as a front light source, which may provide a third light L3, so that the third light L3 passes through the substrate SUB containing the test cell, and advances to the third optical film assembly 206 to form a fourth light. The inspection light receiver 802 may receive the fourth light L4 to detect the status of the cavity or through via of the test cell of the substrate SUB and generate an inspection result. It should be noted that the third optical film assembly 206 may be or include a reflective film, which may include, for example, but not limited to, metal material or a highly reflective material. In addition, the second inspection light generator 205 may be moved or rotated in different directions (including X-Y, Y-Z, X-Z, or X-Y-Z, referring to the labeling of direction X, direction Y, and direction Z in FIG. 9) to control the incidence angle θ of the third light L3 to be from 10 degrees to 170 degrees, but is not limited to. According to some embodiments, the third light L3 may be a ring-shaped front light source or a backlight source, but not limited thereto. The inspection light receiver 802 may also be disposed at a relative position or angle to facilitate reception of the fourth light L4 to obtain good inspection results. It should be noted that the third optical film assembly 206 may be a film layer directly coated or formed on the surface of the carrier table 207, or it may be a film layer element that may be separated from the carrier table 207. In the inspection step, the above method of making the inspection light receiver 802 or the second inspection light generator 205 not parallel to the normal direction of the surface of the substrate SUB (i.e., the inspection light receiver 802 or the second inspection light generator 205 has a tilting angle for image photography to adjust the angle of the incident light or the light reflected from the object to be measured) may be called the image photographing method in the 2.5D image measurement method to obtain the 2.5D image as shown in FIG. 10.

It should be noted that the inspection device 22 and the inspection device 24 are only embodiments of the present disclosure, and those skilled in the art may make appreciative adjustments according to the system requirement. For example, the inspection light receiver 802 may be a photographic element, such as, but not limited to, a 2D optical microscope (2D-OM). The second inspection light generator 205 may be a ring-shaped front light source that generates a third light L3 in a ring-shaped distribution incident on a portion of the substrate SUB. In addition, the first light L1 and the third light L3 may include visible light (full-color light) with a wavelength greater than 400 nm and invisible light (near-infrared or short-wave infrared light) with a wavelength of 700 nm to 1700 nm, but are not limited thereto. The laser process includes, but is not limited to, the use of laser light having a wavelength of 1064 nm, 532 nm, or 266 nm to perform the rework step.

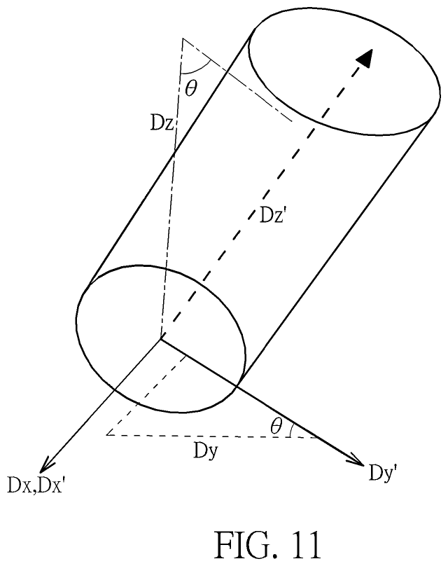

Please refer to FIG. 10. FIG. 10 is a schematic diagram illustrating 2D image and 2.5D image of the through via in the substrate according to the present disclosure. The image captured by the inspection device 22 may be a 2D image, as shown in image (i), in which the opening of the surface of the through via or cavity and the size of the middle (e.g., the waist) or the bottom may be clearly seen. Furthermore, the 2.5D image captured using the inspection device 24 may be a 2D image as shown in image (ii), in which a semi-dimensional image of the opening portion P1 of the through via or cavity and the sidewall portion P2 may be captured, such that the waist profile may be seen, for example, by the sidewall portion P2. In the inspection device 24, due to the setting of the third optical film assembly 206, the 2.5D images and inspection results of the through vias inspected by the presently disclosed inspection device have a high contrast and a high resolution, and the maximum size and the minimum size (i.e., the portion having a waist width) of the through vias may be clearly seen. Furthermore, assuming that the second inspection light generator 205 is moved or rotated in different directions in the X-Z plane to control the angle of incidence θ of the third light line L3 to be from 10 degrees to 170 degrees, the length in the X direction on the 2.5D image is equal to the length in the X direction of the through via, whereas the length in the Y direction on the 2.5D image and the length in the Z direction are reduced and smaller than the length in the Y direction on the through via and the length in the Z direction, respectively. The Y-direction length and Z-direction length of the 2.5D image will be smaller than the Y-direction length and Z-direction length of the through via respectively. Specifically, please refer to FIG. 11, which is a schematic projection of the 2.5D image disclosed herein. As shown in FIG. 11, the conversion between a 2.5D image and a 2D image may be obtained by the triangular function of projection method. For example: Dx=Dx′; Dy=Dy′/cos θ; Dz=Dz′ sin θ*glass refractive index, where Dx, Dy, Dz are the actual lengths of the through vias, and Dx′, Dy′, Dz Dx′, Dy′, and Dz are the actual lengths of the through vias, and Dx′, Dy′, and Dz are the lengths of the through vias in the 2.5D image. Furthermore, since the 2.5D image allows the profile of the sidewalls of the measurement object to be seen, it is possible to observe whether the sidewalls are flat or not. In some embodiments, as shown in image (ii) and image (iii) of FIG. 10, the sidewall portion P2 is not flat or has a shell-like pattern SH, which may be used to determine the execution status of the hole-forming process, for example, to compare the inspected test cell with the aforementioned inspection standard, and then to determine the shaping status of the through via or cavities formed in the circuit region, to determine the need for rework, to proceed to the next manufacturing process step, or to scrap the through via. On the other hand, at the stage of establishing the inspection standard, a database of the inspection standard may be effectively established by collecting profile and/or pattern data of the sidewall portion P2 of the 2.5D image and measuring it against the destructive slices, as described above.

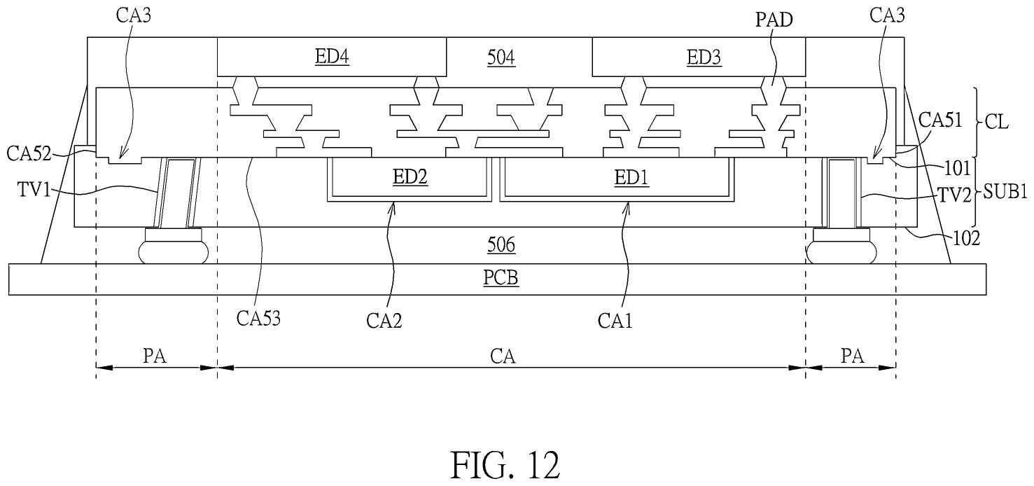

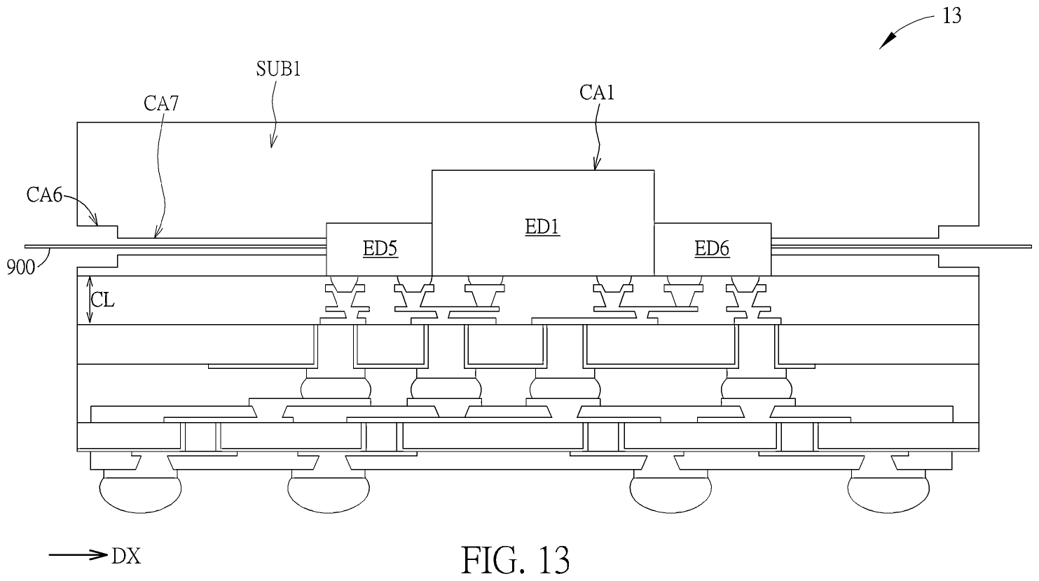

The manufacturing system of the electronic device of the present disclosure is applicable to different embodiments of the electronic device. Please refer to FIGS. 12 and 13, which are schematic diagrams of the electronic device having cavities according to various embodiments of the present disclosure. As shown in FIG. 12, the electronic device 12 is derived from the electronic device 3 of FIG. 3, so the same components are indicated by the same symbols. The difference between the electronic device 12 and the electronic device 3 is that the substrate SUB has cavities for different purposes. Specifically, a first cavity CA1 and a second cavity CA2 of the electronic device 12 are used for a first electronic unit ED1 and a second electronic unit ED2, respectively, in other words, the first cavity CA1 and the second cavity CA2 correspond to the circuit region CA. A third cavity CA3 and a fourth cavity CA4 of the electronic device 12 are used as test cells with different test parameters, respectively, that is, the third cavity CA3 and the fourth cavity CA4 correspond to the peripheral region PA. In the embodiment shown in FIG. 12, the third cavity CA3 and the fourth cavity CA4 are of different sizes, indicating test cells with different test parameters. The electronic device 12 also optionally includes a fifth cavity CA5 in which the above-described circuit region CA and peripheral region PA are provided, that is, the fifth cavity CA5 may demarcate the boundary of the electronic device 13, wherein the sidewalls CA51, sidewalls CA52, and bottom surface CA53 show the profile of the fifth cavity CA5. It should be noted that the provision of the third cavity CA3 and the fourth cavity CA4 may also assist in the adhesion effect between the substrate SUB and the circuit structure CL. In addition, the electronic device 12 may also include a packaging layer 504 covering and encompassing the third electronic unit ED3 and the fourth electronic unit ED4 and enclosing a contact pad PAD on the lower side thereof. The electronic device 13 may also include a bottom filler layer 506 covering and encompassing the outer periphery of the packaging layer 504 and the first substrate SUB1. As described above, the electronic device 12 shown in FIG. 12 may form an electronic device packaging component.

As shown in FIG. 13, the first cavity CA1 of the electronic device 13 is provided with a first electronic unit ED1, a fifth electronic unit ED5, and a sixth electronic unit ED6, and the fifth electronic unit ED5 and the sixth electronic unit ED6 may be a photonic integrated circuit (PIC) or an electrical integrated circuit (EIC), but not limited thereto. It should be noted that in the horizontal direction DX, the electronic device 13 also has a sixth cavity CA6 and a seventh cavity CA7, wherein the seventh cavity CA7 is a narrow cavity and is disposed in the sixth cavity CA6. In addition, the seventh cavity CA7 may serve as a waveguide and have a fiber optic 900 disposed therein. As described above, the electronic device 13 of FIG. 13 may form a photonic device packaging element. By designing the sixth cavity CA6 and monitoring the accuracy (e.g., roughness or levelness) of the sixth cavity CA6 during the process, the alignment accuracy or the production efficiency of the electronic device during the assembly of the optical fiber 900 may be improved, but not limited to.

As can be seen from the above, the electronic device manufacturing method of the present disclosure performs a real-time non-destructive inspection step on the cavities or through vias of the substrate, and then determines whether the cavities or through vias of the substrate need to be reworked or not. The present disclosure may provide inspection results with good contrast or resolution compared to the prior art. In this way, the rework process of electronic devices may be performed more efficiently, thereby reducing costs.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a first substrate having a first surface and a second surface opposite to each other, wherein the first substrate comprises a first cavity disposed in the first surface, and the first cavity having a first bottom surface;
a first electronic unit disposed in the first cavity;
a circuit structure disposed on the first surface and the first electronic unit; and
a printed circuit board electrically connected to the first electronic unit through the circuit structure,
wherein a roughness of the first bottom surface of the first cavity is greater than a roughness of the first surface.

2. The electronic device of claim 1, wherein in a sectional structure of the electronic device, the first cavity comprises two sidewalls connected to the first bottom surface individually, and a height difference of the two sidewalls is in a range greater than or equal to 0 micrometers and less than or equal to 20 micrometers.

3. The electronic device of claim 2, wherein in the sectional structure of the electronic device, a connection between one of the two sidewalls and the first bottom surface has a curved profile.

4. The electronic device of claim 2, wherein in the sectional structure of the electronic device, a connection between one of the two sidewalls and the first bottom surface has a chamfering profile.

5. The electronic device of claim 1, wherein an angle between an extension direction of the first bottom surface and an extension direction of the first substrate is in a range greater than 0 degrees and less than or equal to 10 degrees, wherein the extension direction of the first substrate is perpendicular to a normal direction of the first substrate.

6. The electronic device of claim 1, wherein the first substrate further comprises a second cavity adjacent to the first cavity, and the electronic device further comprises:
a second electronic unit disposed in the second cavity, wherein the circuit structure is electrically connected to the second electronic unit.

7. The electronic device of claim 6, wherein the second cavity has a second bottom surface, and a difference between a roughness of the second bottom surface and the roughness of the first bottom surface is in a range greater than or equal to 0 micrometers and less than or equal to 20 micrometers.

8. The electronic device of claim 6, wherein an angle between an extension direction of the second bottom surface of the second cavity and an extension direction of the first substrate is in a range greater than or equal to 0 degrees and less than or equal to 10 degrees.

9. The electronic device of claim 6, wherein in a sectional structure of the electronic device, the second cavity has a second sidewall connected to the second bottom surface, the first cavity has a first sidewall connected to the first bottom surface, and a height difference between the second sidewall and the first sidewall is in a range greater than or equal to 0 micrometers and less than or equal to 20 micrometers.

10. The electronic device of claim 1, wherein in a sectional structure of the electronic device, a first distance is provided between a central portion of the first bottom surface and the second surface, and a second distance is provided between a connection of the first bottom surface and a sidewall of the first cavity and the second surface, and the first distance is greater than the second distance.

11. The electronic device of claim 1, wherein the first substrate comprises a first through via connecting the first surface and the second surface of the first substrate, and the electronic device further comprises:
a second substrate, coupled to the second surface of the first substrate, wherein the second substrate has a third surface and a fourth surface opposite to each other, the third surface is disposed between the second surface and the fourth surface, and the second substrate comprises a second through via connecting the third surface and the fourth surface,
wherein the first through via overlaps at least a portion of the second through via in a normal direction of the first substrate.

12. The electronic device of claim 11, wherein in the normal direction of the first substrate, the first through via has a first projection area, the second through via has a second projection area, and a distance between a first circle center of the first projection area and a second circle center of the second projection area is less than or equal to 10 micrometers.

13. The electronic device of claim 11, wherein the first substrate and the second substrate have a thickness within a range from 25 micrometers to 500 micrometers respectively.

14. The electronic device of claim 11, wherein in the normal direction of the first substrate, an angle is provided between the normal direction and a sidewall profile of at least one of the first through via and the second through via.

15. An electronic device manufacturing method, comprising:
providing a substrate, wherein the substrate comprises a circuit region and a peripheral region adjacent to the circuit region, and the peripheral region comprises a plurality of test areas;
performing a via-forming process on the substrate, wherein the via-forming process comprises forming a test cell in each of the plurality of test areas;
performing a test cell inspection step to the plurality of test cells and comparing an inspection result with an inspection standard to obtain a comparison result;
based on the comparison result, determining whether parameters of the via-forming process need to be modified, or determining whether at least one through via or cavity of the substrate is qualified or needs to be reworked or whether the substrate needs to be scrapped; and
forming a conductive layer in the at least one through via or providing an electronic unit in the at least one cavity when the at least one through via or cavity is determined to be qualified.

16. The electronic device manufacturing method of claim 15, wherein the test cell inspection step comprises:
providing a first light, allowing the first light to pass through a first optical film assembly and then pass through at least one of the plurality of test cells; and
allowing the first light to pass through a second optical film assembly to form a second light and using a camera unit to receive the second light to obtain the inspection result.

17. The electronic device manufacturing method of claim 16, wherein the test cell inspection step further comprises:
providing a third optical film assembly;
allowing the substrate to be disposed on the third optical film assembly;
providing a third light, and allowing the third light to pass through the at least one of the plurality of test cells and travel to the third optical film assembly to form a fourth light;
utilizing the camera unit to receive the fourth light or the second light to obtain the inspection result.

18. The electronic device manufacturing method of claim 17, wherein an angle is provided between the first light or the third light with a normal direction of a surface of the substrate, and the angle is greater than 0 degrees and less than 90 degrees.

19. The electronic device manufacturing method of claim 16, wherein the camera unit has a tilt angle corresponding to a normal direction of the substrate.

20. The electronic device manufacturing method of claim 16, further comprising:
establishing the inspection standard, wherein a method of establishing the inspection standard comprises:
in an inspection standard establishment stage, using a 2.5D image measurement method to obtain a 2.5D image of the at least one through via or cavity;
when the 2.5D image shows that one of the at least one through via or cavity has an uneven sidewall, performing a destructive measurement to the one of the at least through via or cavity having the uneven sidewall to obtain a parametric data of the uneven sidewall, and collecting the parametric data and the 2.5D image corresponding to the parametric data; and
repeating above steps, and establishing the inspection standard based on the collected parametric data and 2.5D image.
